(19) United States
(12) Patent Application Publication
(10) Pub. No.: US 2025/0118576 A1
(43) Pub. Date: Apr. 10, 2025

(54) CHAMBER KITS, PROCESSING CHAMBERS, AND METHODS FOR GAS ACTIVATION IN SEMICONDUCTOR MANUFACTURING

(71) Applicant: Applied Materials, Inc., Santa Clara, CA (US)

(72) Inventors: Chen-Ying WU, Santa Clara, CA (US); Zuoming ZHU, Sunnyvale, CA (US); Abhishek DUBE, Fremont, CA (US); Ala MORADIAN, Sunnyvale, CA (US); Errol Antonio C. SANCHEZ, Tracy, CA (US); Martin Jeffrey SALINAS, San Jose, CA (US); Aniketnitin PATIL, San Jose, CA (US); Raja Murali DHAMODHARAN, Madurai (IN); Shu-Kwan LAU, Sunnyvale, CA (US)

(21) Appl. No.: 18/391,089

(22) Filed: Dec. 20, 2023

(30) Foreign Application Priority Data
Oct. 6, 2023 (IN) 202341067022

(51) Int. Cl. H01L 21/67; H01L 21/02; H01L 21/687

(52) U.S. Cl. CPC H01L 21/6719; H01L 21/0228; H01L 21/67017; H01L 21/67098; H01L 21/68742

(57) ABSTRACT

Embodiments of the present disclosure relate to chamber kits, processing chambers, and related methods and components for gas activation applicable for semiconductor manufacturing. In one or more embodiments, a processing chamber includes a chamber body and one or more heat sources configured to heat a processing volume of the chamber body. The chamber body includes one or more gas inject passages formed in the chamber body, and one or more gas exhaust passages formed in the chamber body. The processing chamber includes a first pre-heat ring that includes a first opaque surface, and a second pre-heat ring that includes a second opaque surface. The first pre-heat ring and the second pre-heat ring define a first gas flow path between the first opaque surface and the second opaque surface, and the first gas flow path in fluid communication with at least one of the one or more gas inject passages.

### CROSS-REFERENCE TO RELATED APPLICATION

This application claims priority to India patent application No. 202341067022, filed Oct. 6, 2023, which is herein incorporated by reference in its entirety.

### BACKGROUND

### Field

Embodiments of the present disclosure relate to chamber kits, processing chambers, and related methods and components for gas activation applicable for semiconductor manufacturing.

### Description of the Related Art

Semiconductor substrates are processed for a wide variety of applications, including the fabrication of integrated devices and micro-devices. One method of processing substrates includes depositing a material, such as a dielectric material or a semiconductor material, on an upper surface of the substrate. The material may be deposited in a lateral flow chamber by flowing a process gas parallel to the surface of a substrate positioned on a support, and thermally decomposing the process gas to deposit a material from the gas onto the substrate surface.

However, operations (such as epitaxial deposition operations) can be long, expensive, and inefficient, and can have limited capacity and throughput. Moreover, hardware can involve relatively large dimensions that occupy higher footprints in manufacturing facilities. Additionally, processing can involve non-uniformities, which can involve hindered device performance and/or reduced throughput. For example, activation of gases can be limited and/or can involve non-uniform activation, which can cause limited and/or non-uniform film growth and/or dopant concentration. Such issues can be exacerbated in batch processing operations.

Therefore, a need exists for improved apparatuses and methods in semiconductor processing.

### SUMMARY

Embodiments of the present disclosure relate to chamber kits, processing chambers, and related methods and components for gas activation applicable for semiconductor manufacturing.

In one or more embodiments, a processing chamber applicable for semiconductor manufacturing includes a chamber body and one or more heat sources configured to heat a processing volume of the chamber body. The chamber body includes one or more gas inject passages formed in the chamber body, and one or more gas exhaust passages formed in the chamber body. The processing chamber includes a first pre-heat ring that includes a first opaque surface, and a second pre-heat ring that includes a second opaque surface. The first pre-heat ring and the second pre-heat ring define a first gas flow path between the first opaque surface and the second opaque surface, and the first gas flow path in fluid communication with at least one of the one or more gas inject passages.

In one or more embodiments, a chamber kit applicable for semiconductor manufacturing includes a first pre-heat ring that includes a first opaque surface, and a second pre-heat ring that includes a second opaque surface. The chamber kit includes a plate that includes at least one opaque outer surface. The plate includes an outer diameter that is lesser than inner diameters of the first pre-heat ring and the second pre-heat ring.

In one or more embodiments, a method of substrate processing includes positioning a substrate in a processing volume of a chamber. The method includes heating the substrate, and flowing one or more process gases into the processing volume. The one or more process gases include a reactive element and a dopant element. The flowing includes flowing the one or more process gases through a flow path defined between a pair of opaque surfaces prior to flowing over a surface of the first substrate. The method includes depositing one or more layers on the surface of the first substrate at a growth rate that is 360 Angstroms-per-minute or higher.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional side view of a processing apparatus, according to one or more embodiments.

FIG. 2 is a schematic cross-sectional side view of the processing apparatus shown in FIG. 1, according to one or more embodiments.

FIG. 3 is a schematic partial cross-sectional side view of the processing apparatus including the chamber kit shown in FIG. 1, according to one or more embodiments.

FIG. 4 is a schematic partial cross-sectional side view of a chamber kit that can be used in the processing apparatus shown in FIG. 1, according to one or more embodiments.

FIG. 5 is a schematic partial cross-sectional side view of a chamber kit that can be used in the processing apparatus shown in FIG. 1, according to one or more embodiments.

FIG. 6 is a schematic partial cross-sectional side view of a chamber kit that can be used in the processing apparatus shown in FIG. 1, according to one or more embodiments.

FIG. 7 is a schematic partial cross-sectional side view of a chamber kit that can be used in the processing apparatus shown in FIG. 1, according to one or more embodiments.

FIG. 8 is a schematic partial cross-sectional side view of a chamber kit that can be used in the processing apparatus shown in FIG. 1, according to one or more embodiments.

FIG. 9 is a schematic partial cross-sectional side view of a chamber kit that can be used in the processing apparatus shown in FIG. 1, according to one or more embodiments.

FIG. 10 is a schematic partial cross-sectional side view of a chamber kit that can be used in the processing apparatus shown in FIG. 1, according to one or more embodiments.

FIG. 11 is a schematic partial cross-sectional side view of a chamber kit that can be used in the processing apparatus shown in FIG. 1, according to one or more embodiments.

FIG. 12 is a schematic partial cross-sectional side view of a chamber kit that can be used in the processing apparatus shown in FIG. 1, according to one or more embodiments.

FIG. 13 is a schematic block diagram view of a method of substrate processing, according to one or more embodiments.

FIG. 14 is a schematic graphical view of a graph showing film growth rates and dopant concentrations for chamber kit configurations, according to one or more embodiments.

FIG. 15 is a schematic graphical view of a graph plotting activation energy versus plate temperature, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to chamber kits, processing chambers, and related methods and components for gas activation applicable for semiconductor manufacturing. In one or more embodiments, gas activation (such as pre-activation and activation over the substrate) is facilitated to increase film growth rates and/or increase dopant concentration in formed films. The subject matter described herein can be used to process a single substrate at a time or two or more substrates simultaneously.

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

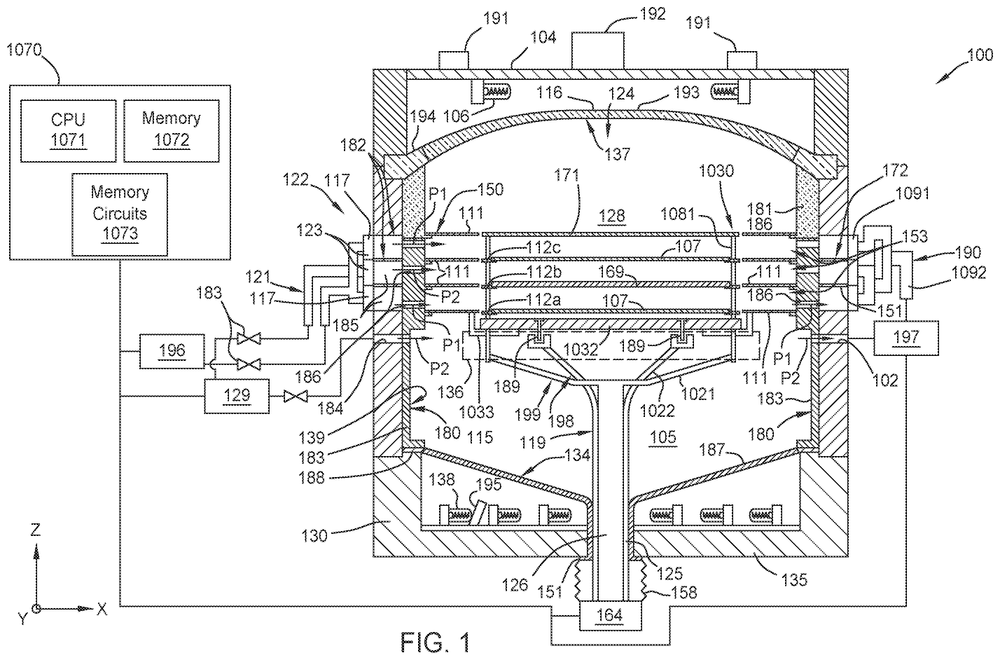

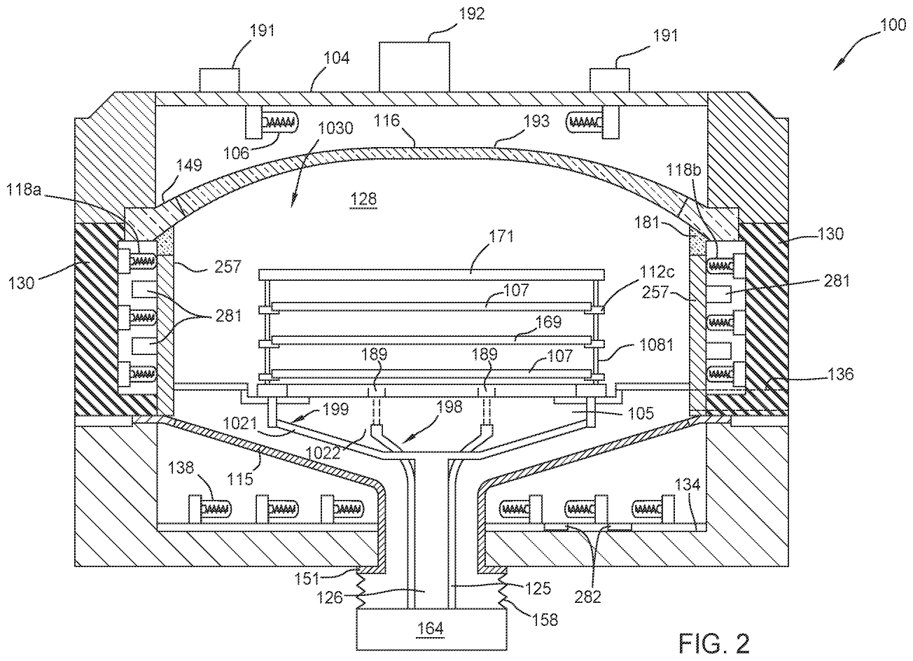

FIG. 1 is a schematic cross-sectional side view of a processing chamber 100, according to one or more embodiments. The side heat sources 118a, 118b shown in FIG. 2 are not shown in FIG. 1 for visual clarity purposes. The processing chamber 100 includes a processing chamber having a chamber body 130 that defines an internal volume 124. The internal volume 124 includes a processing volume 128.

A chamber kit 150 is positioned in the processing volume 128 and at least partially supported by a substrate support assembly 119 (such as a pedestal assembly). The chamber kit 150 includes a first plate 1032, a second plate 171, and a plurality of levels that support a plurality of substrates 107 (two are shown) for simultaneous processing (e.g., epitaxial deposition). The present disclosure contemplates that the first plate 1032 can be omitted. In the implementation shown in FIG. 1, the chamber kit 150 supports two substrates. The chamber kit 150 can support other numbers of substrates, including but not limited to three substrates 107, four substrates 107, six substrates 107, or eight or more substrates 107. The processing chamber 100 includes an upper window 116, such as a dome, disposed between a lid 104 and the processing volume 128.

The processing chamber 100 includes a lower window 115 disposed below the processing volume 128. One or more upper heat sources 106 are positioned above the processing volume 128 and the upper window 116. The one or more upper heat sources 106 can be radiant heat sources such as lamps, for example halogen lamps. The one or more upper heat sources 106 are disposed between the upper window 116 and the lid 104. The upper heat sources 106 are positioned to facilitate uniform heating of the substrates 107. One or more lower heat sources 138 are positioned below the processing volume 128 and the lower window 115. The one or more lower heat sources 138 can be radiant heat sources such as lamps, for example halogen lamps. The lower heat sources 138 are disposed between the lower window 115 and a floor 134 of the internal volume 124. The lower heat sources 138 are positioned to facilitate uniform heating of the substrates 107. A bias heat source 195 is oriented toward the first lift frame 199 and/or the second lift frame 198.

The present disclosure contemplates that other heat sources may be used (in addition to or in place of the lamps) for the various heat sources described herein. For example, resistive heaters, light emitting diodes (LEDs), and/or lasers may be used for the various heat sources described herein.

The upper and lower windows 116, 115 may be transparent to the infrared radiation, such as by transmitting at least 80% (such as at least 95%) of infrared radiation. The upper and lower windows 116, 115 may be a quartz material (such as a transparent quartz). In one or more embodiments, the upper window 116 includes an inner window 193 and outer window supports 194. The inner window 193 may be a thin quartz window. The outer window supports 194 support the inner window 193 and are at least partially disposed within a support groove. In one or more embodiments, the lower window 115 includes an inner window 187 and outer window supports 188. The inner window 187 may be a thin quartz window. The outer window supports 188 support the inner window 187.

The substrate support assembly 119 is disposed in the processing volume 128. One or more liners 180 are disposed in the processing volume 128 and surround the substrate support assembly 119. The one or more liners 180 facilitate shielding the chamber body 130 from processing chemistry in the processing volume 128. The chamber body 130 is disposed at least partially between the upper window 116 and the lower window 115. The one or more liners 180 are disposed between the processing volume 128 and the chamber body 130. The one or more liners 180 include an upper liner 181 and one or more lower liners 183.

The processing chamber 100 includes one or more gas inject passages 182 formed in the chamber body 130 and in fluid communication with the processing volume 128, and one or more gas exhaust passages 172 (a plurality is shown in FIG. 1) formed in the chamber body 130 opposite the one or more gas inject passages 182. The one or more gas exhaust passages 172 are in fluid communication with the processing volume 128. Each of the one or more gas inject passages 182 and one or more gas exhaust passages 172 are formed through one or more sidewalls of the chamber body 130 and through the one or more liners 180 that line the one or more sidewalls of the chamber body 130.

Each gas inject passage 182 includes a gas channel 185 formed in the chamber body 130 and one or more gas openings 186 (one is shown in FIG. 1) formed in the one or more liners 180. One or more supply conduit systems are in fluid communication with the one or more gas inject passages 182. In FIG. 1, an inner supply conduit system 121 and an outer supply conduit system 122 are in fluid communication with a plurality of gas inject passages 182. The inner supply conduit system 121 includes an inner gas box 123 mounted to the chamber body 130 and in fluid communication with an inner set of the gas inject passages 182. The outer supply conduit system 122 includes a plurality of outer gas boxes 117 mounted to the chamber body 130 and in fluid communication with an outer set of the gas inject passages 182. The present disclosure contemplates that a variety of gas supply systems (e.g., supply conduit system(s), gas inject passages, and/or gas boxes different than what is shown in FIG. 1) may be used.

The processing chamber 100 includes a chamber kit 150. The chamber kit 150 includes a plurality of pre-heat rings 111a-111d positioned outwardly of the substrates 107 and the first and second plates 1032, 171. Four pre-heat rings 111a-111d are shown in FIG. 1. Other numbers (such as two or three) of the pre-heat rings 111 may be used. The chamber kit 150 divides the processing volume into a plurality of flow levels 153 (three flow levels are shown in FIG. 1). In one or more embodiments, the chamber kit 150 includes at least two (such as at least three) flow levels 153. The one or more gas inject passages 182 are positioned as a plurality of inject levels such that each gas inject passage 182 corresponds to one of the plurality of inject levels. Each inject level aligns with a respective flow level 153. The pre-heat rings 111a-111d are coupled to and/or at least partially supported by the one or more liners 180. In one or more embodiments, the pre-heat rings 111a-111d each include a complete ring or one or more ring segments, such as a C-ring segment.

The chamber kit 150 includes a plurality of arcuate supports 112a-112c. A first arcuate support 112a is configured to support one of the substrates 107, a second arcuate support 112b, configured to support the plate 169, and a third arcuate support 112c the other of the substrates 107. The chamber kit 150 also includes one or more support rod structures 1081 (a plurality is shown) that support the arcuate supports 112a-112c. The one or more support rod structures 1081 sized and shaped to extend through the arcuate supports 112a-112c and into the second plate 171. In one or more embodiments, the arcuate supports 112a-112c each include a complete ring or one or more ring segments, such as a C-ring segment.

During operations (such as during an epitaxial deposition operation), one or more process gases P1 are supplied to the processing volume 128 through the outer supply conduit system 122, and through the one or more gas inject passages 182. The one or more process gases P1 are supplied from one or more gas sources 196 in fluid communication with the one or more gas inject passages 182. Each of the gas inject passages 182 is configured to direct the one or more processing gases P1 in a generally radially inward direction towards the chamber kit 150. As such, in one or more embodiments, the gas inject passages 182 may be part of a cross-flow gas injector. The flow(s) of the one or more process gases P1 can be divided into at least some of the plurality of flow levels 153. For at least the uppermost flow level 153 (or a single flow level 153—if a single flow level 153 is used), the one or more process gases P1 can be guided (using the second plate 171) along a streamlined flow path such that diversive flow away from the uppermost substrate 107 (or a single substrate 107—if a single substrate 107 is used) is reduced or eliminated.

The processing chamber 100 includes an exhaust conduit system 190. The one or more process gases P1 can be exhausted through exhaust gas openings formed in the one or more liners 180, exhaust gas channels formed in the chamber body 130, and then through exhaust gas boxes 1091. The one or more process gases P1 can flow from exhaust gas boxes 1091 and to an optional common exhaust box 1092, and then out through a conduit using one or more pump devices 197 (such as one or more vacuum pumps).

The one or more processing gases P1 can include, for example, purge gases, cleaning gases, and/or deposition gases. The deposition gases can include, for example, one or more reactive gases carried in one or more carrier gases. The one or more reactive gases can include, for example, silicon and/or germanium containing gases (such as silane (SiH₄), disilane (Si₂H₆), dichlorosilane (SiH₂Cl₂), and/or germane (GeH₄)), chlorine containing etching gases (such as hydrogen chloride (HCl)), and/or dopant gases (such as phosphine (PH₃) and/or diborane (B₂H₆)). The one or more purge gases can include, for example, one or more of argon (Ar), helium (He), nitrogen (N₂), hydrogen chloride (HCl), and/or hydrogen (H₂).

Purge gas P2 supplied from a purge gas source 129 is introduced to a bottom region 105 of the internal volume 124 through one or more purge gas inlets 184 formed in the sidewall of the chamber body 130. The purge gas P2 can also be supplied through the inner supply conduit system 121 and over a plate 169 positioned between the two substrates 107.

The one or more purge gas inlets 184 are disposed at an elevation below the one or more gas inject passages 182. If the one or more liners 180 are used, a section of the one or more liners 180 may be disposed between the one or more gas inject passages 182 and the one or more purge gas inlets 184. The one or more purge gas inlets 184 are configured to direct the purge gas P2 in a generally radially inward direction. The one or more purge gas inlets 184 may be configured to direct the purge gas P2 in an upward direction. During a film formation process, the substrate support assembly 119 is located at a position that can facilitate the purge gas P2 to flow generally along a flow path across a back side of the first plate 1032. The purge gas P2 exits the bottom region 105 and is exhausted out of the processing chamber 100 through one or more purge gas exhaust passages 102 located on the opposite side of the processing volume 128 relative to the one or more purge gas inlets 184.

The substrate support assembly 119 includes a first lift frame 199 and a second lift frame 198 disposed at least partially about the first lift frame 199. The first lift frame 199 includes first arms 1021 coupled to an outer ring 1033 such that lifting and lowering the first lift frame 199 lifts and lowers the substrates 107, the first plate 1032, the second plate 171, and the plate 169. A plurality of lift pins 189 are suspended from the first plate 1032. Lowering of the first plate 1032 and/or lifting of the second lift frame 198 initiates contact of the lift pins 189 with arms 1022 of the second lift frame 198. Continued lowering of the first plate 1032 and/or lifting of the second lift frame 198 initiates contact of the lift pins 189 with a substrate 107 and/or the plate 169 such that the lift pins 189 raise the substrate 107 and/or the plate 169. A bottom region 105 of the processing chamber 100 is defined between the floor 134 and the cassette 1030. As shown in FIG. 1, the lift pins 189 can be configured to abut against—and be lifted from—the arms 1022.

A first shaft 126 of the first lift frame 199, a second shaft 125 of the second lift frame 198, and a section 151 of the lower window 115 extend through a port formed in a bottom 135 of the chamber body 130 and the floor 134. Each shaft 125, 126 is coupled to one or more respective motors 164, which are configured to independently raise, lower, and/or rotate the substrates 107 and the plate 169 using the first lift frame 199, and to independently raise and lower the lift pins 189 using the second lift frame 198. The first lift frame 199 includes the first shaft 126 and a plurality of first arms 1021 configured to support the first plate 1032, the substrate supports 112, and the second plate 171.

The second lift frame 198 includes the second shaft 125 and the plurality of second arms 1022 configured to interface with and support the lift pins 189. A bellows assembly 158 circumscribes and encloses a portion of the shafts 125, 126 disposed outside the chamber body 130 to facilitate reduced or eliminated vacuum leakage outside the chamber body 130.

An opening 136 (a substrate transfer opening) is formed through the one or more sidewalls of the chamber body 130. The opening 136 may be used to transfer the plate 169 and/or the substrates 107 to or from the arcuate supports 112a-112c, e.g., in and out of the internal volume 124. In one or more embodiments, the opening 136 includes a slit valve. In one or more embodiments, the opening 136 may be connected to any suitable valve that enables the passage of substrates therethrough. The opening 136 is shown in ghost in FIGS. 1 and 2 for visual clarity purposes.

The processing chamber 100 may include one or more sensors 191, 192, 282, such as temperature sensors (e.g., optical pyrometers) or other metrology sensors, which measure temperatures (or other parameters) within the processing chamber 100 (such as on the surfaces of the upper window 116, the first plate 1032, the second plate 171, the plate 169, the arcuate supports 112a-112c, the pre-heat rings 111a-111d, and/or the substrates 107). The one or more sensors 191, 192 are disposed on the lid 104. The one or more sensors 282 (e.g., lower pyrometers)—which are shown in FIG. 2—are disposed on a lower side of the lower window 115. The one or more sensors 282 can be disposed adjacent to and/or on the bottom 135 of the chamber body 130.

In one or more embodiments, upper sensors 191, 192 are oriented toward a top of the second plate 171 and/or a top of a fourth pre-heat ring 111d. In one or more embodiments, side sensors 281 (e.g., side temperature sensors) are oriented toward one or more of the arcuate supports 112a-112c and/or the pre-heat rings 111a-111d. In one or more embodiments, lower sensors 282 are oriented toward a bottom of the chamber kit 150 (such as a lower surface of the first plate 1032, a bottom of the plate second 171, and/or a bottom of the first pre-heat ring 111a.

The processing chamber 100 includes a controller 1070 configured to control the processing chamber 100 or components thereof. For example, the controller 1070 may control the operation of components of the processing chamber 100 using a direct control of the components or by controlling controllers associated with the components. In operation, the controller 1070 enables data collection and feedback from the respective chambers to coordinate and control performance of the processing chamber 100.

The controller 1070 generally includes a central processing unit (CPU) 1071, a memory 1072, and support circuits 1073. The CPU 1071 may be one of any form of a general purpose processor that can be used in an industrial setting. The memory 1072, or non-transitory computer readable medium, is accessible by the CPU 1071 and may be one or more of memory such as random access memory (RAM), read only memory (ROM), floppy disk, hard disk, or any other form of digital storage, local or remote. The support circuits 1073 are coupled to the CPU 1071 and may include cache, clock circuits, input/output subsystems, power supplies, and the like.

The various methods (such as the method 1300) and operations disclosed herein may generally be implemented under the control of the CPU 1071 by the CPU 1071 executing computer instruction code stored in the memory 1072 (or in memory of a particular processing chamber) as, e.g., a software routine. When the computer instruction code is executed by the CPU 1071, the CPU 1071 controls the components of the processing chamber 100 to conduct operations in accordance with the various methods and operations described herein. In one or more embodiments, the memory 1072 (a non-transitory computer readable medium) includes instructions stored therein that, when executed, cause the methods (such as the method 1300) and operations (such as the operations 1302-1308) described herein to be conducted. The controller 1070 can be in communication with the heat sources, the gas sources, and/or the vacuum pump(s) of the processing chamber 100, for example, to cause a plurality of operations to be conducted.

The first plate 1032 and/or the one or more liners 180 (such as the upper liner 181 and/or the one or more lower liners 183), are formed of one or more of quartz (such as transparent quartz, e.g. clear quartz; opaque quartz, e.g. white quartz, or grey quartz; and/or black quartz), silicon carbide (SiC), graphite coated with SiC, and/or one or more ceramics (such as one or more of the exemplary ceramics described below).

FIG. 2 is a schematic cross-sectional side view of the processing chamber 100 shown in FIG. 1, according to one or more embodiments. The cross-sectional view shown in FIG. 2 is rotated by 55 degrees relative to the cross-sectional view shown in FIG. 1.

The processing chamber 100 includes one or more side heat sources 118a, 118b (e.g., side lamps, side resistive heaters, side LEDs, and/or side lasers, for example) positioned outwardly of the processing volume 128. One or more second side heat sources 118b are opposite one or more first side heat sources 118a across the processing volume 128.

In FIG. 2, the pre-heat rings 111a-111d is not shown for visual clarity purposes. In addition to the one or more sensors 191, 192 positioned above the processing volume 128 and above the second plate 171, the processing chamber 100 may include one or more sensors 281, such as temperature sensors (e.g., optical pyrometers) or other metrology sensors, which measure temperatures (or other parameters) within the processing chamber 100. A plurality of windows 257—if used—can be disposed in gaps between or formed in the one or more liners 180 (such as the upper liner 181 and/or the one or more lower liners 183). The one or more sensors 281 are side sensors (e.g., side pyrometers) that are positioned outwardly of the processing volume 128, outwardly of the pre-heat rings 111a-111d (shown in FIG. 1), and outwardly of the plurality of windows 257. The one or more sensors 281 can be radially aligned, for example, with the plurality of windows 257 (as shown in FIG. 2).

The one or more side sensors 281 (such as one or more pyrometers) can be used to measure temperatures within the processing volume 128 from respective sides of the processing volume 128. The side sensors 281 are arranged in a plurality of sensor levels (two sensor levels are shown in FIG. 2). In one or more embodiments, the number of sensor levels is equal to the number of heat source levels. Each side sensor 281 can be oriented horizontally or can be directed (e.g., oriented downwardly at an angle) toward the substrate 107 and the substrate support 112 of a respective level of the cassette 1030.

The present disclosure contemplates that the side heat sources 118a, 118b, the windows 257, and/or the side sensors 281 can be omitted.

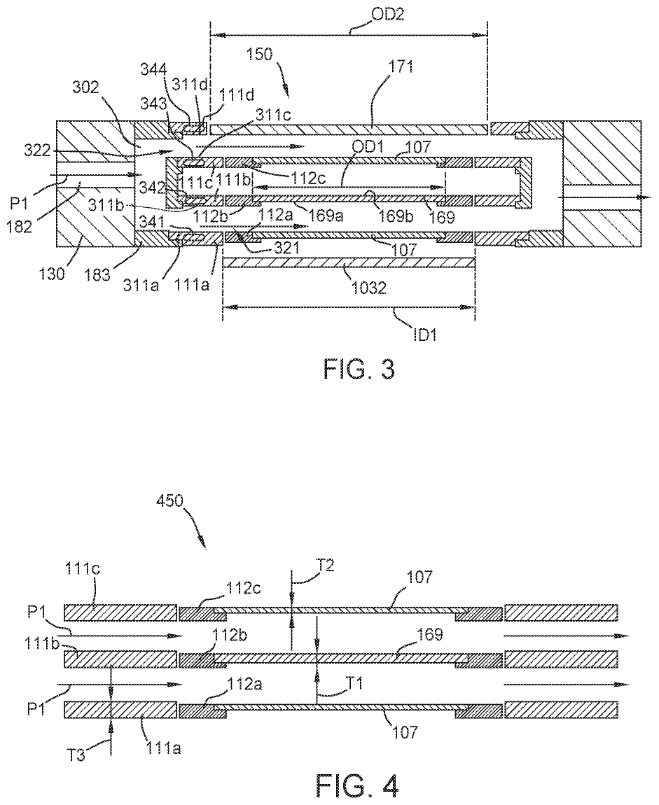

FIG. 3 is a schematic partial cross-sectional side view of the processing chamber 100 including the chamber kit 150 shown in FIG. 1, according to one or more embodiments.

A first pre-heat ring 111a includes a first opaque surface 311a, and a second pre-heat ring 111b includes a second opaque surface 311b. The plate 169 includes at least one opaque outer surface 169a, 169b (two are shown in FIG. 3). The plate 169 includes an outer diameter OD1 that is lesser than inner diameters ID1 of the first pre-heat ring 111a and the second pre-heat ring 111b. A second pre-heat ring 111b includes a second opaque surface 311b. The first pre-heat ring 111a and the second pre-heat ring 111b define a first gas flow path 321 between the first opaque surface 311a and the second opaque surface 311b. The first gas flow path 321 is in fluid communication with at least one of the one or more gas inject passages 182.

A third pre-heat ring 111c includes a third opaque surface 311c, and a fourth pre-heat ring 111d includes a fourth opaque surface 311d. The third pre-heat ring 111c and the fourth pre-heat ring 111d define a second gas flow path 322 between the third opaque surface 311c and the fourth opaque surface 311d. The second gas flow path 322 is in fluid communication with at least one of the one or more gas inject passages 182. In one or more embodiments a level of one or more gas inject passages 182 flows the one or more process gases P1 to a common flow opening 302 formed in the one or more liners 180. The common flow opening 302 flows the one or more process gases P1 to the first gas flow path 321 and the second gas flow path 322.

A first arcuate support 112a is sized and shaped for positioning within the first pre-heat ring 111a, and a second arcuate support 112b spaced from the first arcuate support 112a. The second arcuate support 112b is sized and shaped for positioning within the second pre-heat ring 111b. A third arcuate support 112c is spaced from the second arcuate support 112b, and the third arcuate support 112c is sized and shaped for positioning within the third pre-heat ring 111c. The plate 169 is supported by the second arcuate support 112b. The second plate 171 is sized and shaped for positioning within the fourth pre-heat ring 111d. The second plate 171 includes a second outer diameter OD2 is larger than the outer diameter OD1 of the plate 169. In one or more embodiments, the plate 169 and/or the second plate 171 are discal in shape.

The opaque surfaces 311a-311d and the opaque surfaces 169a, 169b are each part of an opaque material, and the opaque material includes one or more of opaque quartz (such as white quartz, grey quartz, and/or black quartz), silicon carbide (SiC), one or more ceramics (such as alumina (aluminum oxide (Al₂O₃)), Aluminum nitride (AlN), Silicon Nitride (Si₃N₄), Boron Nitride (BN), and/or Boron Carbide (B₄C)), and/or graphite coated with SiC. In one or more embodiments, the opaque material is transmissive for 10% or less of light having a wavelength in the infrared (IR) range and/or the visible range. In one or more embodiments, the opaque material has an absorptivity that is at least 30% for light having a wavelength in the IR range and/or the visible range. In one or more embodiments, the opaque surfaces 311a-311d and the opaque surfaces 169a, 169b are each a white surface, a grey surface, and/or a black surface. In one or more embodiments, a portion of the one or more liners 180 extends between the second pre-heat ring 111b and the third pre-heat ring 111c to block the one or more process gases P1 such that the one or more process gases P1 do not flow between the plate 169 and the upper substrate 107. The opaque surfaces and/or opaque material described herein (e.g., for the pre-heat rings 111a-111c, the plate 169, and/or the second plate 171) can at least partially function as a heat sink, which can facilitate gas activation and/or temperature uniformity across substrates 107 during processing.

In one or more embodiments, the first pre-heat ring 111a, the second pre-heat ring 111b, and the plate 169 are each formed of silicon carbide (SiC). In one or more embodiments, the third pre-heat ring 111c, the fourth pre-heat ring 111d, and the second plate 171 are each formed of SiC. A first heating element 341 is embedded in the first pre-heat ring 111a, a second heating element 342 is embedded in the second pre-heat ring 111b, and a third heating element 343 is embedded in the third pre-heat ring 111c. A controller (such as the controller 1070) is configured to independently control a supply of power to the respective heating elements 341-343. For example, the controller can independently control a supply of power to the third heating element 343 relative to the first heating element 341. In one or more embodiments, the heating elements 341-343 include an electrical line (such as an electrical rod) and/or an electrical mesh that receives direct current (DC) power and/or radiofrequency (RF) power. In one or more embodiments, two heating elements are disposed to heat opposing sides of each gas flow path 321, 322 for each substrate 107.

In the implementation shown in FIG. 3, one or more layers are deposited on upper sides of the two substrates 107 using the one or more process gases P1.

FIG. 4 is a schematic partial cross-sectional side view of a chamber kit 450 that can be used in the processing chamber 100 shown in FIG. 1, according to one or more embodiments.

The chamber kit 450 is similar to the chamber kit 150 implementations shown in FIG. 1 and FIG. 3, and includes one or more of the aspects, features, components, operations, and/or properties thereof. In the implementation shown in FIG. 4, three pre-heat rings 111a-111c and three arcuate supports 112a-112c are included for the chamber kit 450, and the second plate 171 is omitted. The first plate 1032 can be included or omitted. In the implementation shown in FIG. 4, one or more layers are deposited on an upper side of the lower substrate 107 and a lower side of the upper substrate 107 using the one or more process gases P1.

The plate 169 has a thickness T1 that is at least 1 mm. In one or more embodiments, the second plate 171 and/or the pre-heat rings 111a-111c have a respective thickness T2, T3 that is at least 1 mm.

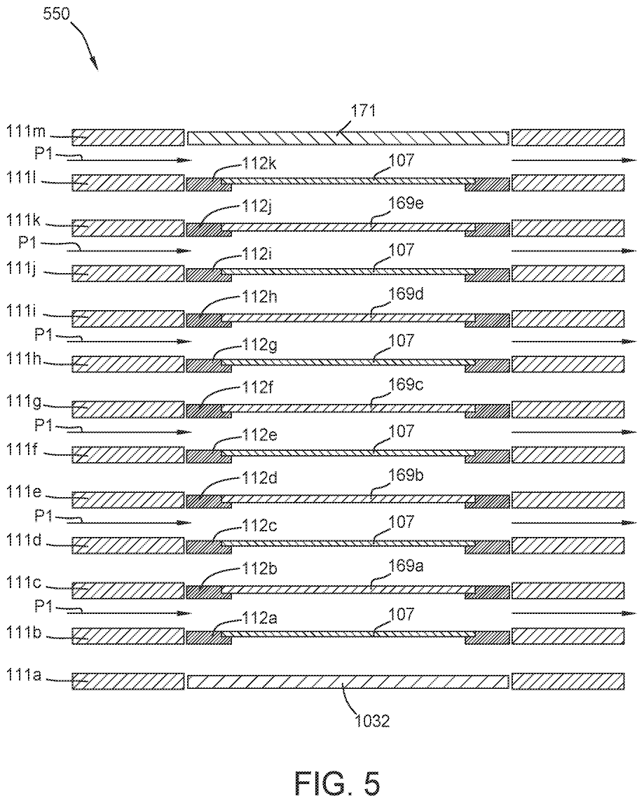

FIG. 5 is a schematic partial cross-sectional side view of a chamber kit 550 that can be used in the processing chamber 100 shown in FIG. 1, according to one or more embodiments.

The chamber kit 550 is similar to the chamber kit 150 implementations shown in FIG. 1 and FIG. 3, and includes one or more of the aspects, features, components, operations, and/or properties thereof. In the implementation shown in FIG. 5, thirteen pre-heat rings 111a-111m, eleven arcuate supports 112a-112k, and five plates 169a-169e are included for the chamber kit 550. The chamber kit 550 supports six substrates 107. A plate 169a-169e including at least one opaque surface is disposed adjacently above each substrate 107. In the implementation shown in FIG. 5, one or more layers are deposited on upper sides of the six substrates 107 using the one or more process gases P1. In one or more embodiments, the one or more process gases P1 are blocked from flowing over upper sides of the plates 169a-169e. In one or more embodiments, the one or more purge gases P2 flow over or are blocked from flowing over upper sides of the plates 169a-169e.

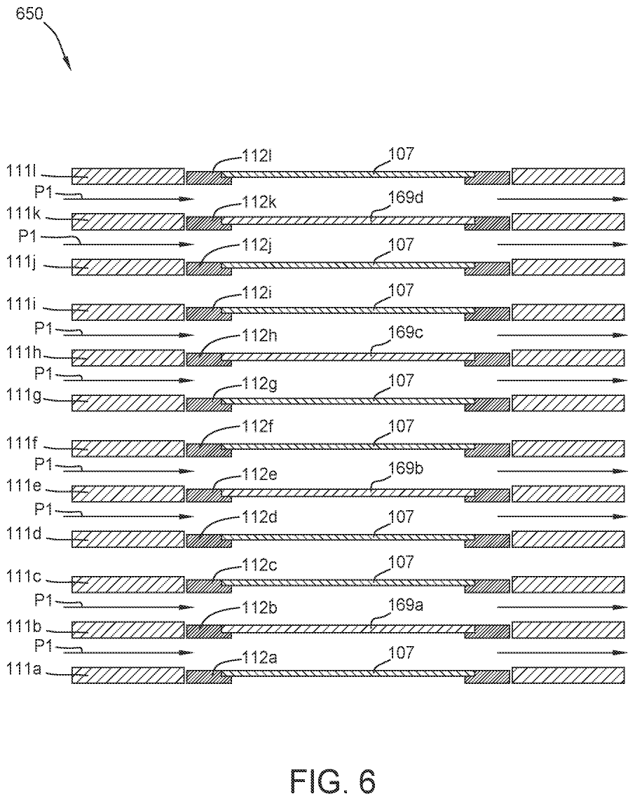

FIG. 6 is a schematic partial cross-sectional side view of a chamber kit 650 that can be used in the processing chamber 100 shown in FIG. 1, according to one or more embodiments.

The chamber kit 650 is similar to the chamber kit 150 implementations shown in FIG. 1 and FIG. 3, and includes one or more of the aspects, features, components, operations, and/or properties thereof. In the implementation shown in FIG. 6, twelve pre-heat rings 111a-1111, twelve arcuate supports 112a-1121, and four plates 169a-169d are included for the chamber kit 650. The chamber kit 650 supports eight substrates 107. In the implementation shown in FIG. 6, one or more layers are deposited on upper sides of four of the eight substrates 107, and one or more layers are deposited on lower sides of fourth of the other four of the eight substrates 107, using the one or more process gases P1. In one or more embodiments, the one or more process gases P1 are blocked from flowing between adjacent substrates 107. In one or more embodiments, the one or more purge gases P2 flow between or are blocked from flowing between adjacent substrates 107. A plate 169a-169d including at least one opaque surface is disposed adjacently above each substrate 107 that is having one or more layers deposited on an upper side thereof. A plate 169a-169d is disposed adjacently below each substrate 107 that is having one or more layers deposited on a lower side thereof. In one or more embodiments, the second plate 171 is omitted for the chamber kit 650. The first plate 1032 can be included or omitted.

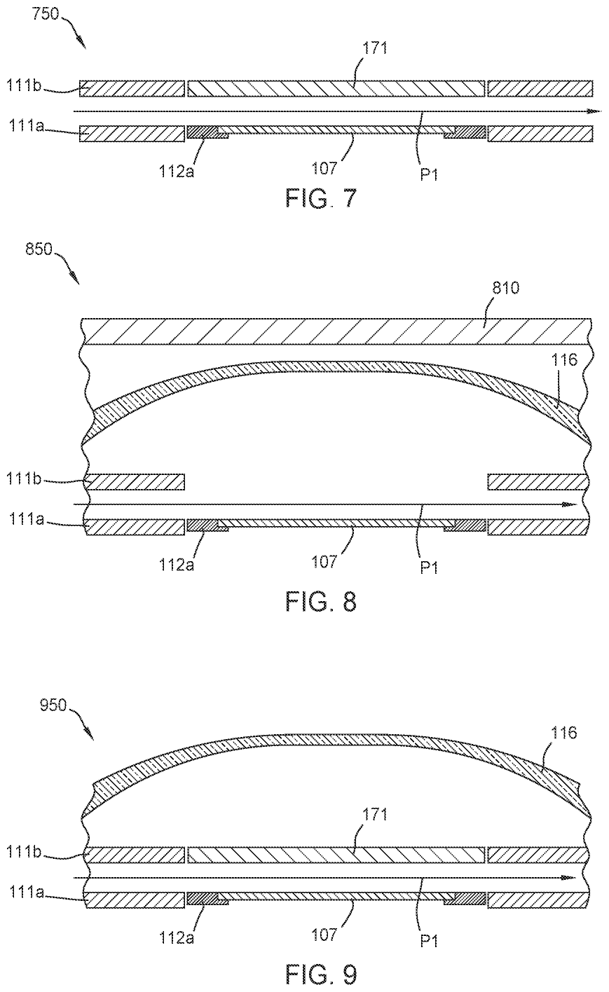

FIG. 7 is a schematic partial cross-sectional side view of a chamber kit 750 that can be used in the processing chamber 100 shown in FIG. 1, according to one or more embodiments.

The chamber kit 750 is similar to the chamber kit 150 implementations shown in FIG. 1 and FIG. 3, and includes one or more of the aspects, features, components, operations, and/or properties thereof. In the implementation shown in FIG. 7, two pre-heat rings 111a-111b, the second plate 171, and a single arcuate support 112a are included for the chamber kit 750. The chamber kit 750 supports a single substrate 107. In the implementation shown in FIG. 7, one or more layers are deposited on an upper side of the substrate 107 using the one or more process gases P1. The first plate 1032 can be included or omitted.

FIG. 8 is a schematic partial cross-sectional side view of a chamber kit 850 that can be used in the processing chamber 100 shown in FIG. 1, according to one or more embodiments.

The chamber kit 850 is similar to the chamber kit 750 implementation shown in FIG. 7, and includes one or more of the aspects, features, components, operations, and/or properties thereof. In the implementation shown in FIG. 8, the upper heat sources 106 are omitted (while the lower heat sources 138 are included), and a reflective plate 810 is disposed above the pre-heat rings 111a, 111b and/or above the upper window 116. The first plate 1032 can be included or omitted. The second plate 171 is omitted. The reflective plate 810 can be formed of a reflective material and/or can be coated with the reflective material. In one or more embodiments, the reflective material includes gold (Au) and/or polished aluminum. The reflective plate 810 has a reflectivity that is at least 80% (such as 90% or more) for radiation from the substrate. In one or more embodiments, the reflectivity is for radiation having a wavelength in the infrared (IR) range and/or the visible range. In the implementation shown in FIG. 8, one or more layers are deposited on an upper side of the substrate 107 using the one or more process gases P1. The chamber kit 850 can be used to process a single substrate 107 (as shown in FIG. 7) or a plurality of substrates (as shown in FIG. 1).

FIG. 9 is a schematic partial cross-sectional side view of a chamber kit 950 that can be used in the processing chamber 100 shown in FIG. 1, according to one or more embodiments.

The chamber kit 950 is similar to the chamber kit 850 implementation shown in FIG. 8, and includes one or more of the aspects, features, components, operations, and/or properties thereof. In the implementation shown in FIG. 9, the upper heat sources 106 are omitted (while the lower heat sources 138 are included), the reflective plate 810 is omitted, and the second plate 171 is disposed between the single substrate 107 and the upper window 116. In the implementation shown in FIG. 9, one or more layers are deposited on an upper side of the substrate 107 using the one or more process gases P1. The chamber kit 950 can be used to process a single substrate 107 (as shown in FIG. 9) or a plurality of substrates (as shown in FIG. 1).

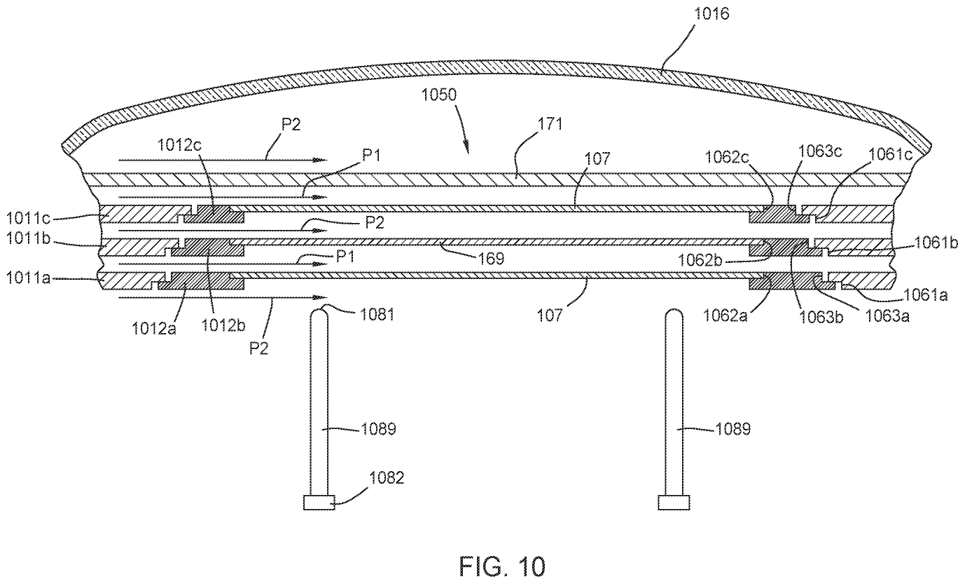

FIG. 10 is a schematic partial cross-sectional side view of a chamber kit 1050 that can be used in the processing chamber 100 shown in FIG. 1, according to one or more embodiments.

The chamber kit 1050 is similar to the chamber kit 150 implementations shown in FIG. 1 and FIG. 3, and includes one or more of the aspects, features, components, operations, and/or properties thereof. In the implementation shown in FIG. 10, the chamber kit 1050 includes three pre-heat rings 1011a-1011c, three arcuate supports 1012a-1012c, and the plate 169. The chamber kit 1050 supports two substrates 107.

In the implementation shown in FIG. 4, one or more layers are deposited on upper sides of the two substrates 107 using the one or more process gases P1. In one or more embodiments, the one or more purge gases P2 flow over lower sides of the substrates 107. The second plate 171 can be supported by the one or more support rod structures 1081, or the second plate 171 can be supported by one or more inner ledges of the upper liner 181. The second plate 171 can include the at least one opaque surface, or the second plate 171 can be formed of a transparent material (such as transparent quartz, e.g. clear quartz). The first plate 1032 can be included or omitted.

The pre-heat rings 1011a-1011c respectively include recessed inner surfaces 1061a-1061c that define inner ledges. Inner diameters of the recessed inner surfaces 1061a-1061c and the inner ledges gradually decrease from a lowermost pre-heat ring 1011a and to an uppermost pre-heat ring 1011c. For example, the first pre-heat ring 1011a includes a first recessed inner surface 1061a having a first inner diameter, the second pre-heat ring 1011b includes a second recessed inner surface 1061b having a second inner diameter that is lesser than the first inner diameter, and the third pre-heat ring 1011c includes a third recessed inner surface 1061c having a third inner diameter that is lesser than the second inner diameter.

The arcuate supports 1012a-1012c respectively include recessed inner surfaces 1062a-1062c that define inner ledges, and recessed outer surfaces 1063a-1063c that define outer ledges. Outer diameters of the recessed outer surfaces 1063a-1063c and the outer ledges gradually decrease from a lowermost arcuate support 1012a and to an uppermost arcuate support 1012c. The inner ledges of the pre-heat rings 1011a-1011c respectively overlap with the outer edges of the arcuate supports 1012a-1012c. The inner ledges of the arcuate supports 1012a-1012c respectively support the two substrates 107 and the plate 169. A plurality of lift pins 1089 respectively include a curved section 1083 configured to interface with the substrates 107 and/or the plate 169, and a head section 1082 configured to interface with the arms 1022 of the second lift frame 198.

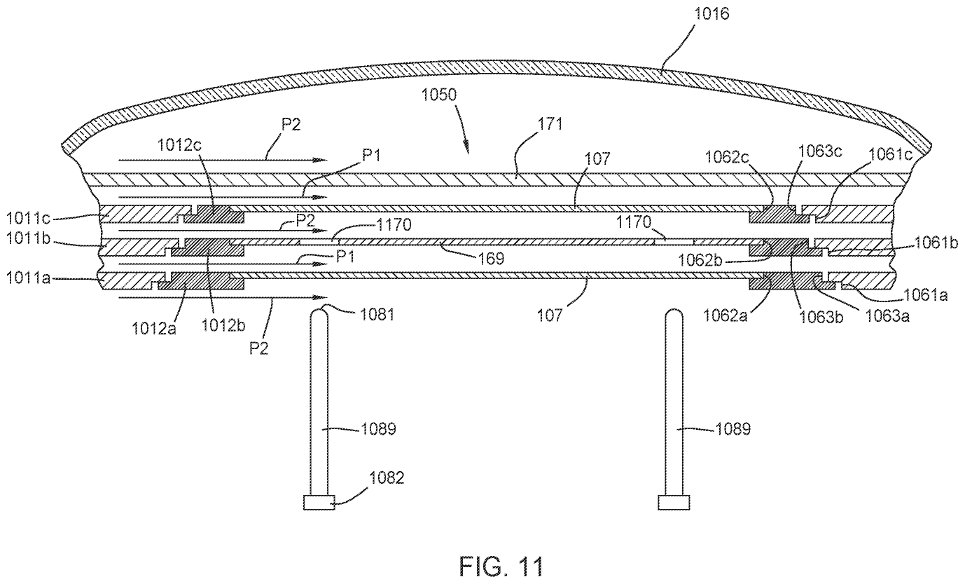

FIG. 11 is a schematic partial cross-sectional side view of a chamber kit 1150 that can be used in the processing chamber 100 shown in FIG. 1, according to one or more embodiments.

The chamber kit 1150 is similar to the chamber kit 1050 implementations shown in FIG. 10, and includes one or more of the aspects, features, components, operations, and/or properties thereof. In the implementation shown in FIG. 11, the plate 169 of the chamber kit 1150 includes a plurality of openings 1170 extending therethrough. The plurality of openings 1170 are sized and shaped to receive the plurality of lift pins 1089 therethrough. In such an embodiment, the lower substrate 107 can firstly be lifted from the first arcuate support 1012a such that the lower substrate 107 can be transferred out of the processing chamber 100.

The lift pins 1089 can then extend through the openings 1170 to contact the upper substrate 107 and lift the upper substrate from the third arcuate support 1012c such that the upper substrate 107 can be transferred out of the processing chamber 100.

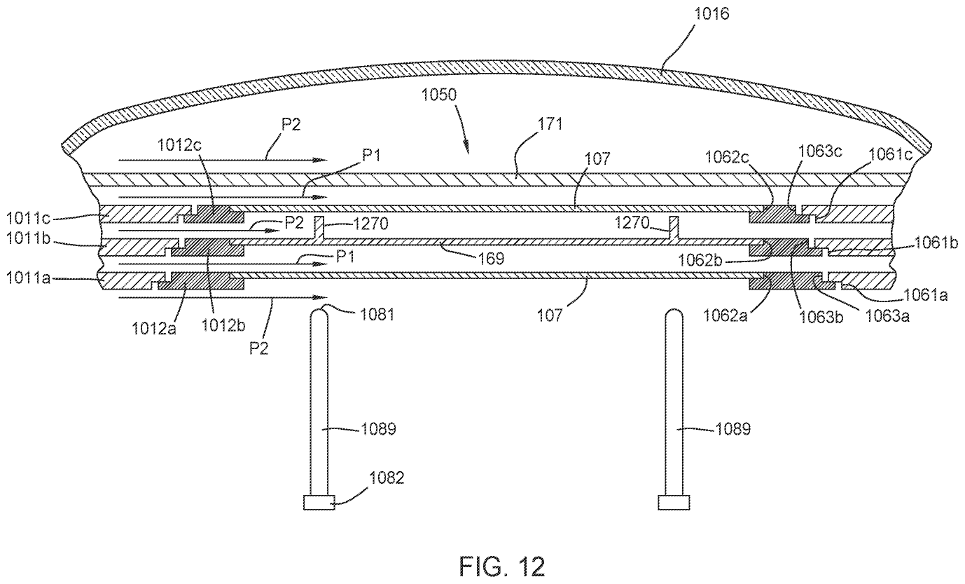

FIG. 12 is a schematic partial cross-sectional side view of a chamber kit 1250 that can be used in the processing chamber 100 shown in FIG. 1, according to one or more embodiments.

The chamber kit 1250 is similar to the chamber kit 1050 implementations shown in FIG. 10, and includes one or more of the aspects, features, components, operations, and/or properties thereof. In the implementation shown in FIG. 12, the plate 169 of the chamber kit 1250 includes a plurality of columns 1270 extending relative to a side of the plate 169. In such an embodiment, the lower substrate 107 can firstly be lifted from the first arcuate support 1012a such that the lower substrate 107 can be transferred out of the processing chamber 100.

The lift pins 1089 can then contact the plate 169 and lift the plate 169 from the second arcuate support 1012b such that the columns 1270 contact the upper substrate 107 and lift the upper substrate 107 from the third arcuate support 1012c such that the upper substrate 107 can be transferred out of the processing chamber 100.

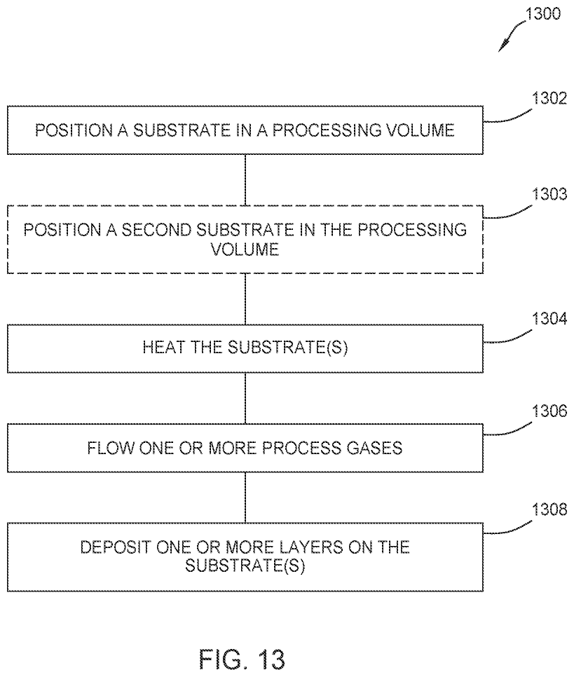

FIG. 13 is a schematic block diagram view of a method 1300 of substrate processing, according to one or more embodiments.

Operation 1302 includes positioning a substrate in a processing volume of a chamber.

Optional operation 1303 includes positioning a second substrate in the processing volume of the chamber and at a spacing from the substrate. In one or more embodiments, one or more additional substrates are positioned in the processing volume and at a spacing from the second substrate and from each other.

Operation 1304 includes heating the substrate, the second substrate (if included), and the one or more additional substrates (if included). In one or more embodiments, the substrates are heated using a target temperature within a range of 300 degrees Celsius to 1100 degrees Celsius.

Operation 1306 includes flowing one or more process gases into the processing volume. In one or more embodiments, the one or more process gases include a reactive element (such as silicon (Si)) and a dopant element (such as phosphorus). The flowing includes flowing the one or more process gases through a flow path defined between a pair of opaque surfaces prior to flowing over a surface of the substrate. In one or more embodiments, the flowing includes flowing the one or more process gases through a second flow path defined between a second pair of opaque surfaces prior to flowing over a second surface of the second substrate. In one or more embodiments, the one or more process gases flow through the processing volume at a pressure within a range of 5 Torr to 600 Torr.

Operation 1308 includes depositing one or more layers on the surface of the substrate. In one or more embodiments, the one or more layers are deposited on the substrate at a growth rate that is 300 Angstroms-per-minute or higher. In one or more embodiments, the growth rate is 350 Angstroms-per-minute or higher, such as 360 Angstroms-per-minute or higher. In one or more embodiments, a the deposited one or more layers have a dopant concentration that is 3.5E21 or higher, such as 4.0E21 atoms/centimeters³ or higher, or 4.05E21 atoms/centimeters³ or higher, for example 4.1E21 atoms/centimeters³ or higher. The growth rate and the dopant concentration can be used on at least a central region of the substrate or the one or more layers. In one or more embodiments, the method 1300 includes depositing one or more second layers on the second surface of the second substrate (if included) at a growth rate that is 80 Angstroms-per-minute or higher, such as 90 Angstroms-per-minute or higher, for example 92 Angstroms-per-minute or higher. In one or more embodiments, the deposited one or more layers substrate (if included) have the dopant concentration that is 3.5E21 or higher, such as 4.0E21 atoms/centimeters³ or higher, or 4.05E21 atoms/centimeters³ or higher, for example 4.1E21 atoms/centimeters³ or higher. The growth rate and the dopant concentration can be used on at least a central region of the second substrate or the one or more second layers.

The present disclosure contemplates that operations (such as operation 1304 and operation 1306) can be conducted at least partially simultaneously.

As described herein, it is contemplated that for each gas flow path that deposits (e.g., epitaxially) film on a substrate, the respective gas flow path is bounded on opposing sides thereof by two opaque surfaces of pre-heat rings. Downstream of the pre-heat rings, the respective gas flow path is also bounded on opposing sides thereof by two opaque surfaces of arcuate supports. Downstream of the arcuate supports, the respective gas flow path can also bounded on opposing sides thereof by an opaque surface of a plate and the surface of the substrate being deposited upon, or the respective gas flow path can also bounded on opposing sides thereof by two surfaces of two respective substrates being deposited upon.

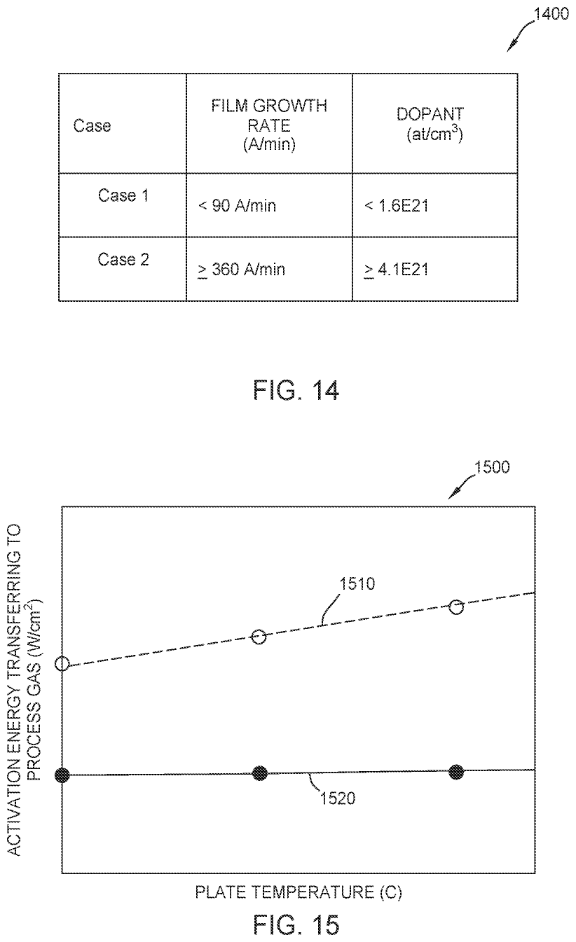

FIG. 14 is a schematic graphical view of a graph 1400 showing film growth rates and dopant concentrations for chamber kit configurations, according to one or more embodiments.

Case 2 shows information for a chamber kit configuration using subject matter described herein. Case 1 shows information for another chamber kit configuration.

As shown for Case 1 it is believed that during processing, a respective substrate can have film growth at a growth rate of less than 90 Angstroms-per-minute, and after processing the one or more layers can have a dopant concentration of less than 1.6E21 atoms/centermeters³.

As shown for Case 2 it is also believed that during processing, aa respective substrate 107 can have film growth at a growth rate of greater than 90 Angstroms-per-minute, such as about 320 Angstroms-per-minute or higher (for example about 360 Angstroms-per-minute or higher), and after processing the one or more layers can have a dopant concentration of about 4.1E21 atoms/centermeters³ or higher. Other growth rates and dopant concentrations are contemplated.

Using subject matter described herein higher film growth rates and/or higher dopant concentrations can be achieved. The present disclosure also contemplates that the growth rate and/or the dopant concentration can be made more uniform across a plurality of substrates. For example, the growth rate and/or the dopant concentration of an upper substrate (as shown in FIG. 3) can be increased to be more uniform with respect to the lower substrate (as shown in FIG. 3). As an example, the controller can apply a higher power to the third heating element 343 and the fourth heating element 344 relative to the first heating element 341 and the second heating element 342 shown in FIG. 3. The heating elements 341-344 and/or the heat sources 106, 138 can be independently controlled to independently control the temperatures of the pre-heat rings 111a-111d to facilitate more uniform film deposition and/or modularity of process recipes across the substrates 107.

FIG. 15 is a schematic graphical view of a graph 1500 plotting activation energy versus plate temperature, according to one or more embodiments.

A first profile 1510 shows the activation energy believed to be transferred to process gas flowing past the second plate 171 (shown in FIG. 3) during processing operations. A second profile 1520 shows the activation energy believed to be transferred to process gas flowing past another plate during processing operations. As shown by the graph 1500, subject matter described herein (such as the opaue material of the second plate 171) facilitates a high activation energy transferred to process gas, and a larger increase in the activation energy as the temperature of the second plate 171 increases. The higher activation facilitates higher film growth rates and/or higher dopant concentrations for processing.

Benefits of the present disclosure include more efficient and effective activation of process gases; higher film growth rates; higher dopant concentrations; and more uniform film growth rates and/or dopant concentrations. Benefits of the present disclosure also include increased throughput; enhanced device performance; thermal control and adjustability for zones; and quick and efficient heating of zones.

Such benefits can be facilitated for processing a single substrate at a time, and/or batch processing a plurality of substrates simultaneously. For example, film growth rate uniformity and/or dopant concentration uniformity can be enhanced across substrates processed using batch processing

It is contemplated that one or more aspects disclosed herein may be combined. As an example, one or more aspects, features, components, operations, and/or properties of the various implementations of the processing chamber 100, the chamber kit 150, one or more of the heating elements 341-344, the chamber kit 450, the chamber kit 550, the chamber kit 650, the chamber kit 750, the chamber kit 850, the chamber kit 950, the chamber kit 1050, the chamber kit 1150, the chamber kit 1250, the method 1300, the graph 1400, and/or the graph 1500 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

1. A processing chamber applicable for semiconductor manufacturing, comprising:
a chamber body comprising:
a processing volume,
one or more gas inject passages formed in the chamber body, and
one or more gas exhaust passages formed in the chamber body;
one or more heat sources configured to heat the processing volume;
a first pre-heat ring comprising a first opaque surface; and
a second pre-heat ring comprising a second opaque surface, the first pre-heat ring and the second pre-heat ring defining a first gas flow path between the first opaque surface and the second opaque surface, and the first gas flow path in fluid communication with at least one of the one or more gas inject passages.

2. The processing chamber of claim 1, further comprising:
a first arcuate support sized and shaped for positioning within the first pre-heat ring; and
a second arcuate support spaced from the first arcuate support, the second arcuate support sized and shaped for positioning within the second pre-heat ring.

3. The processing chamber of claim 2, further comprising: a plate supported by the second arcuate support, the plate comprising at least one opaque outer surface.

4. The processing chamber of claim 3, wherein the first pre-heat ring, the second pre-heat ring, and the plate are each formed of silicon carbide (SiC).

5. The processing chamber of claim 3, further comprising:
a third pre-heat ring comprising a third opaque surface;
a fourth pre-heat ring comprising a fourth opaque surface, the third pre-heat ring and the fourth pre-heat ring defining a second gas flow path between the third opaque surface and the fourth opaque surface, and the second gas flow path in fluid communication with at least one of the one or more gas inject passages; and
a third arcuate support spaced from the second arcuate support, the third arcuate support sized and shaped for positioning within the third pre-heat ring.

6. The processing chamber of claim 5, further comprising a second plate sized and shaped for positioning within the fourth pre-heat ring, wherein:
the second plate includes a second outer diameter that is larger than an outer diameter of the plate; and
the third pre-heat ring, the fourth pre-heat ring, and the second plate are each formed of SiC.

7. The processing chamber of claim 5, further comprising:
a respective heating element disposed in each of the first pre-heat ring, the second pre-heat ring, the third pre-heat ring, and the fourth pre-heat ring; and
a controller configured to independently control a supply of power of the respective heating elements relative to each other.

8. A chamber kit applicable for semiconductor manufacturing, comprising:
a first pre-heat ring comprising a first opaque surface;
a second pre-heat ring comprising a second opaque surface; and
a plate comprising at least one opaque outer surface, the plate including an outer diameter that is lesser than inner diameters of the first pre-heat ring and the second pre-heat ring.

9. The chamber kit of claim 8, wherein the first pre-heat ring, and the second pre-heat ring, and the plate are each formed of an opaque material, and the plate is discal in shape.

10. The chamber kit of claim 8, further comprising a second plate, wherein the second plate includes a second outer diameter that is larger than the outer diameter of the plate.

11. The chamber kit of claim 9, further comprising a reflective plate, wherein the reflective plate has a reflectivity of at least 80%.

12. The chamber kit of claim 9, further comprising a heating element embedded in one or more of the first pre-heat ring or the second pre-heat ring.

13. The chamber kit of claim 9, wherein the plate has a thickness that is at least 1 mm.

14. The chamber kit of claim 8, further comprising:
an arcuate support configured to support the plate; and
one or more support rod structures sized and shaped to extend through the arcuate support.

15. The chamber kit of claim 8, wherein the plate further comprises a plurality of columns extending relative to a side of the plate.

16. The chamber kit of claim 8, wherein the plate further comprises a plurality of openings extending therethrough, the plurality of openings sized and shaped to receive a plurality of lift pins therethrough.

17. The chamber kit of claim 8, wherein the first pre-heat ring comprises a first recessed inner surface having a first inner diameter, and the second pre-heat ring comprises a second recessed inner surface having a second inner diameter that is lesser than the first inner diameter.

18. The chamber kit of claim 8, wherein the first pre-heat ring and the second pre-heat ring each includes a complete ring or one or more ring segments.

19. A method of substrate processing, comprising:
positioning a substrate in a processing volume of a chamber;
heating the substrate;
flowing one or more process gases into the processing volume, the one or more process gases comprising a reactive element and a dopant element, and the flowing comprising:
flowing the one or more process gases through a flow path defined between a pair of opaque surfaces prior to flowing over a surface of the substrate; and
depositing one or more layers on the surface of the substrate at a growth rate that is 360 Angstroms-per-minute or higher.

20. The method of 19, wherein the reactive element includes silicon (Si), the dopant element includes phosphorus (P), and the one or more layers has a dopant concentration that is 4.1E21 atoms/centimeters³ or higher.
